(19) United States
(12) Patent Application Publication
(10) Pub. No.: US 2019/0304824 A1
(43) Pub. Date: Oct. 3, 2019

(54) PLASMA PROCESSING APPARATUS AND METHOD OF TRANSFERRING WORKPIECE

(71) Applicant: TOKYO ELECTRON LIMITED, Tokyo (JP)

(72) Inventors: Takayuki SUZUKI, Miyagi (JP); Wataru TAKAYAMA, Miyagi (JP); Takahiro MURAKAMI, Miyagi (JP); Kimihiro FUKASAWA, Miyagi (JP); Shinichiro HAYASAKA, Miyagi (JP)

(73) Assignee: TOKYO ELECTRON LIMITED, Tokyo (JP)

(21) Appl. No.: 16/369,707

(22) Filed: Mar. 29, 2019

(30) Foreign Application Priority Data
Mar. 29, 2018 (JP) 2018-063604

(51) Int. Cl. H01L 21/677; H01L 21/67; H01L 21/311; H01L 21/687; H01J 37/20; H01J 37/32

(52) U.S. Cl. CPC H01L 21/67739; H01L 21/67017; H01L 21/31116; H01J 37/32724; H01J 37/20; H01J 37/32623; H01L 21/68742

(57) ABSTRACT

A plasma processing apparatus includes a placing table having a placing surface on which a workpiece is placed to be subjected to a plasma processing; an elevator configured to raise and lower the workpiece with respect to the placing surface of the placing table; and an elevator controller configured to control the elevator, during a period until a transfer of the workpiece begins after a completion of the plasma processing on the workpiece, to hold the workpiece at a position where the placing surface of the placing table and the workpiece are spaced apart from each other by a distance that prevents an intrusion of a reaction product, and control the elevator, when the transfer of the workpiece begins, to raise the workpiece from the position where the workpiece is held.

### CROSS-REFERENCE TO RELATED APPLICATIONS

This application is based on and claims priority from Japanese Patent Application No. 2018-063604, filed on Mar. 29, 2018, with the Japan Patent Office, the disclosure of which is incorporated herein in its entirety by reference.

### TECHNICAL FIELD

The present disclosure relates to a plasma processing apparatus and a method of transferring a workpiece.

### BACKGROUND

A plasma processing apparatus has been known in the related art in which a plasma processing is performed on a workpiece such as, for example, a semiconductor wafer using plasma. Such a plasma processing apparatus includes a placing table configured to place the workpiece thereon in, for example, a processing container capable of configuring a vacuum space. A lifter pin is accommodated within the placing table. In the plasma processing apparatus, when transferring the workpiece on which the plasma processing has been performed, the lifter pin protrudes from the placing table by a driving mechanism, and the workpiece is raised from a placing surface of the placing table by the lifter pin. In addition, in the plasma processing apparatus, the plasma processing may be performed in a state where the placing table is cooled to a temperature of 0° C. or lower. See, for example, Japanese Patent Laid-open Publication Nos. 2016-207840 and 2017-103388.

### SUMMARY

A plasma processing apparatus according to one aspect of the present disclosure includes a placing table having a placing surface on which a workpiece is placed to be subjected to a plasma processing; an elevator configured to raise and lower the workpiece with respect to the placing surface of the placing table; and an elevator controller configured to control the elevator, during a period until a transfer of the workpiece begins after a completion of the plasma processing on the workpiece, to hold the workpiece at a position where the placing surface of the placing table and the workpiece are spaced apart from each other by a distance that prevents an intrusion of a reaction product, and control the elevator, when the transfer of the workpiece begins, to raise the workpiece from the position where the workpiece is held.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic cross-sectional view illustrating a configuration of a plasma processing apparatus according to an embodiment.

FIG. 2 is a block diagram illustrating an exemplary schematic configuration of a control unit which controls the plasma processing apparatus according to an embodiment.

FIG. 3 is a view illustrating an exemplary relationship between the distance between a placing surface of a placing table and a wafer and the length of the intrusion range of a reaction product into the placing surface measured on the basis of the end of the wafer.

FIG. 4 is a view illustrating an exemplary state where the wafer is raised from the placing surface of the placing table.

FIG. 5 is a flowchart illustrating an exemplary flow of a processing of transferring a wafer according to an embodiment.

### DETAILED DESCRIPTION

In the following detailed description, reference is made to the accompanying drawings, which form a part of the present disclosure. The illustrative embodiments described in the detailed description, drawing, and claims are not meant to be in any way limiting. Other embodiments may be utilized, and other changes may be made without departing from the spirit or the scope of the subject matter presented here.

A plasma processing apparatus has been known in the related art in which a plasma processing is performed on a workpiece such as, for example, a semiconductor wafer using plasma. Such a plasma processing apparatus includes a placing table configured to place the workpiece thereon in, for example, a processing container capable of configuring a vacuum space. A lifter pin is accommodated within the placing table. In the plasma processing apparatus, when transferring the workpiece on which the plasma processing has been performed, the lifter pin protrudes from the placing table by a driving mechanism, and the workpiece is raised from a placing surface of the placing table by the lifter pin. In addition, in the plasma processing apparatus, the plasma processing may be performed in a state where the placing table is cooled to a temperature of 0° C. or lower.

By the way, in the plasma processing apparatus, when the plasma processing is performed on the workpiece, a reaction product is generated and adheres to and accumulates on, for example, an inner wall of the processing container. A part of the reaction product accumulated on, for example, the inner wall of the processing container may volatilize from the reaction product and float, as a gas, in the processing container, and may adhere again to the placing surface of the placing table. For example, in the plasma processing apparatus, when transferring the workpiece on which the plasma processing has been performed, since the workpiece is raised from the placing surface of the placing table by the lifter pin, the reaction product may intrude into a gap between the placing surface of the placing table and the workpiece and may adhere to the placing surface of the placing table. In particular, when the plasma processing is performed in a state where the placing table is cooled to a temperature of 0° C. or lower, since condensation of the reaction product floating as a volatile gas easily occurs, the reaction product tends to adhere to the placing surface of the placing table. The adherence of the reaction product to the placing surface of the placing table is undesirable because it causes abnormality such as, for example, poor attraction of the workpiece to the placing surface of the placing table.

[Configuration of Plasma Processing Apparatus]

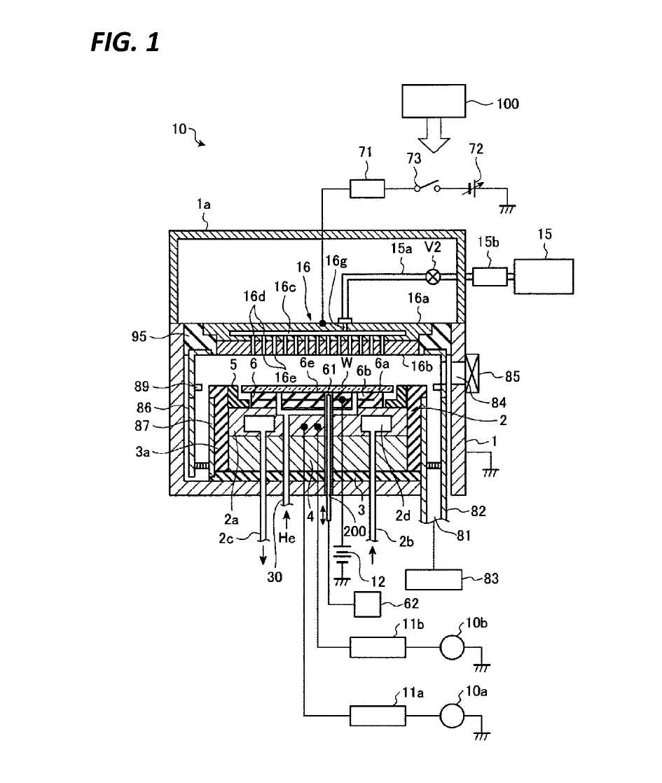

FIG. 1 is a schematic cross-sectional view illustrating a configuration of a plasma processing apparatus 10 according to an embodiment. The plasma processing apparatus 10 includes a processing container 1 which is configured to be hermetically sealed and has an electrical ground potential. The processing container 1 has a cylindrical shape and is formed of, for example, aluminum. The processing container 1 defines a processing space in which plasma is generated. A placing table 2 configured to horizontally support a semiconductor wafer (hereinafter briefly referred to as “wafer”) as a workpiece is provided in the processing container 1. The placing table 2 includes a base 2a and an electrostatic chuck (ESC) 6. The base 2a is formed of a conductive metal such as, for example, aluminum, and functions as a lower electrode. The electrostatic chuck 6 has a function of electrostatically attracting the wafer W. The placing table 2 is supported on a support stand 4. The support stand 4 is supported on a support member 3 formed of, for example, quartz. A focus ring 5 formed of, for example, single crystal silicon is provided on the upper periphery of the placing table 2. In addition, a cylindrical inner wall member 3a formed of, for example, quartz is provided in the processing container 1 so as to surround the periphery of the placing table 2 and the support stand 4.

A first RF power supply 10a is connected to the base 2a via a first matcher 11a, and a second RF power supply 10b is connected to the base 2a via a second matcher 11b. The first RF power supply 10a is used for plasma generation, and is configured to supply radio-frequency power having a predetermined frequency to the base 2a of the placing table 2. In addition, the second RF power supply 10b is used for ion drawing-in (bias), and is configured to supply radio-frequency power having a predetermined frequency lower than that of the first RF power supply 10a to the base 2a of the placing table 2. In this way, the placing table 2 is configured to enable application of a voltage thereto. Meanwhile, a shower head 16 functioning as an upper electrode is provided above the placing table 2 so as to face the placing table 2 in parallel. The shower head 16 and the placing table 2 function as a pair of electrodes (the upper electrode and the lower electrode).

The electrostatic chuck 6 is formed in a disc shape having a flat upper surface, and the upper surface is a placing surface 6e on which the wafer W is placed. The electrostatic chuck 6 is constituted by interposing an electrode 6a between insulators 6b, and a DC power supply 12 is connected to the electrode 6a. Then, when a DC voltage is applied from the DC power supply 12 to the electrode 6a, the wafer W is attracted by the Coulomb force.

A coolant flow path 2d is formed inside the placing table 2, and a coolant inlet pipe 2b and a coolant outlet pipe 2c are connected to the coolant flow path 2d. Then, the placing table 2 is configured to be controllable to a predetermined temperature by circulating an appropriate coolant such as, for example, cooling water in the coolant flow path 2d. In addition, a gas supply pipe 30 is provided to penetrate, for example, the placing table 2 in order to supply a cold heat transfer gas (backside gas) such as, for example, helium gas to the back surface of the wafer W. The gas supply pipe 30 is connected to a gas supply source (not illustrated). With these configurations, the wafer W attracted to and held on the upper surface of the placing table 2 by the electrostatic chuck 6 is controlled to a predetermined temperature.

A plurality of, for example, three pin through-holes 200 (only one is illustrated in FIG. 1) are formed in the placing table 2, and lifter pins 61 are arranged inside the respective pin through-holes 200. Each lifter pin 61 is connected to an elevating mechanism 62. The elevating mechanism 62 raises and lowers the lifter pin 61 to operate the lifter pin 61 so as freely protrude and retreat with respect to the placing surface 6e of the placing table 2. In a state where the lifter pin 61 is raised, the tip of the lifter pin 61 protrudes from the placing surface 6e of the placing table 2, and the wafer W is held above the placing surface 6e of the placing table 2 by the lifter pin 61. Meanwhile, in a state where the lifter pin 61 is lowered, the tip of the lifter pin 61 is accommodated in the pin through-hole 200, and the wafer W is placed on the placing surface 6e of the placing table 2. In this way, the elevating mechanism 62 raises and lowers the wafer W with respect to the placing surface 6e of the placing table 2 by the lifter pin 61. In addition, in a state where the lifter pin 61 is raised, the elevating mechanism 62 holds the wafer W above the placing surface 6e of the placing table 2 by the lifter pin 61.

The shower head 16 is provided in a ceiling wall portion of the processing container 1. The shower head 16 includes a body portion 16a and an upper ceiling plate 16b forming an electrode plate, and is supported on the upper portion of the processing container 1 via an insulating member 95. The body portion 16a is formed of a conductive material, for example, aluminum having an anodized surface, and is configured to be capable of freely removably supporting the upper ceiling plate 16b thereunder.

A gas diffusion chamber 16c is provided within the body portion 16a. In addition, a plurality of gas flow holes 16d are formed in the bottom portion of the body portion 16a so as to be located under the gas diffusion chamber 16c. In addition, gas introduction holes 16e are provided in the upper ceiling plate 16b so as to penetrate the upper ceiling plate 16b in the thickness direction. The gas introduction holes 16e overlap the respective gas flow holes 16d. With this configuration, a processing gas supplied to the gas diffusion chamber 16c is dispersed and supplied in a shower shape into the processing container 1 through the gas flow holes 16d and the gas introduction holes 16e.

A gas introduction port 16g is formed in the body portion 16a to introduce the processing gas into the gas diffusion chamber 16c. One end of a gas supply pipe 15a is connected to the gas introduction port 16g. A processing gas supply source (gas supply unit) 15 is connected to the other end of the gas supply pipe 15a to supply the processing gas. The gas supply pipe 15a is provided with a mass flow controller (MFC) 15b and an opening/closing valve V2 in this order from the upstream side. The processing gas for plasma etching is supplied from the processing gas supply source 15 to the gas diffusion chamber 16c through the gas supply pipe 15a. The processing gas is dispersed and supplied in a shower shape from the gas diffusion chamber 16c into the processing container 1 through the gas flow holes 16d and the gas introduction holes 16e.

A variable DC power supply 72 is electrically connected to the shower head 16 as the above-mentioned upper electrode via a low pass filter (LPF) 71. The variable DC power supply 72 is configured to be capable of turning on or off the supply of power by an on/off switch 73. The current/voltage of the variable DC power supply 72 and the ON/OFF of the on/off switch 73 are controlled by a control unit 100 to be described later. In addition, as will be described later, when radio frequency waves are applied to the placing table 2 from the first RF power supply 10a and the second RF power supply 10b and plasma is generated in the processing space, the control unit 100 turns on the on/off switch 73 as needed, so that a predetermined DC voltage is applied to the shower head 16 as the upper electrode.

A cylindrical ground conductor 1a is provided so as to extend from the side wall of the processing container 1 to a position higher than the height of the shower head 16. The cylindrical ground conductor 1a has a ceiling wall at the top thereof.

An exhaust port 81 is formed in the bottom portion of the processing container 1. A first exhaust device 83 is connected to the exhaust port 81 via an exhaust pipe 82. The first exhaust device 83 includes a vacuum pump, and is configured to depressurize the inside of the processing container 1 to a predetermined degree of vacuum by operating the vacuum pump. Meanwhile, a carry-in/carry-out port 84 for the wafer W is provided in the sidewall of the processing container 1, and a gate valve 85 is provided in the carry-in/carry-out port 84 to open and close the carry-in/carry-out port 84.

At the inner side portion of the processing container 1, a deposition shield 86 is provided along the inner wall surface. The deposition shield 86 prevents byproducts (deposits) of etching from adhering to the processing container 1. A conductive member (GND block) 89 which is connected to a ground to enable control of a ground potential is provided on the deposition shield 86 at substantially the same height as the wafer W, which prevents abnormal discharge. In addition, a deposition shield 87 is provided on the lower end of the deposition shield 86 and extends along the inner wall member 3a. The deposition shields 86 and 87 are freely removable.

An operation of the plasma processing apparatus 10 configured as described above is totally controlled by the control unit 100. The control unit 100 is, for example, a computer, and controls each unit of the plasma processing apparatus 10.

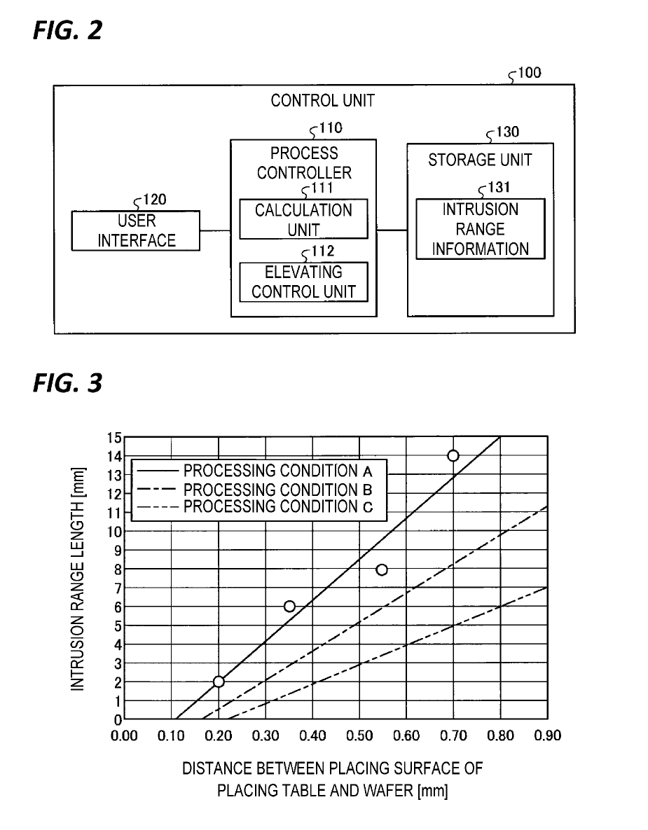

FIG. 2 is a block diagram illustrating an exemplary schematic configuration of the control unit 100 which controls the plasma processing apparatus 10 according to an embodiment. The control unit 100 includes a process controller 110, a user interface 120, and a storage unit 130.

The process controller 110 includes a central processing unit (CPU), and controls each unit of the plasma processing apparatus 10.

The user interface 120 is configured with, for example, a keyboard, through which a process manager inputs a command to manage the plasma processing apparatus 10, or a display which visually displays the operation state of the plasma processing apparatus 10.

The storage unit 130 stores a control program (software) for realizing various processings executed by the plasma processing apparatus 10 under the control of the process controller 110 or a recipe in which, for example, processing condition data is stored. For example, intrusion range information 131 is stored in the storage unit 130. In addition, the control program or the recipe such as, for example, processing condition data may be stored in a computer readable computer recording medium (e.g., an optical disk such as, for example, a hard disk or a DVD, a flexible disk, or a semiconductor memory), for example. Alternatively, the control program or the recipe such as, for example, processing condition data may be frequently transmitted from another device via a dedicated line, for example, and may be used online.

The intrusion range information 131 is data that indicates a relationship between the distance between the placing surface 6e of the placing table 2 and the wafer W and the length of the intrusion range of a reaction product into the placing surface 6e measured on the basis of the end of the wafer W for each processing condition of a plasma processing on the wafer W. FIG. 3 is a view illustrating an exemplary relationship between the distance between the placing surface 6e of the placing table 2 and the wafer W and the length of the intrusion range of a reaction product to the placing surface 6e measured on the basis of the end of the wafer W. FIG. 3 illustrates, for example, the result of measuring the length of the intrusion range of the reaction product into the placing surface 6e on the basis of the end of the wafer W while changing the distance between the placing surface 6e of the placing table 2 and the wafer W. In addition, in the measurement of FIG. 3, a measurement sample in which the placing table 2 and the wafer W are simulated by flat plates that vertically face each other is prepared, and the length of the intrusion range of the reaction product into a surface of the lower flat plate is measured as the length of the intrusion range of the reaction product into the placing surface 6e. In FIG. 3, for each processing condition of the plasma processing on the wafer W (processing conditions A to C), the relationship between the distance between the placing surface 6e of the placing table 2 and the wafer W and the length of the intrusion range of the reaction product into the placing surface 6e measured on the basis of the end of the wafer W is illustrated. The processing conditions of the plasma processing on the wafer W include conditions such as, for example, the type of a processing gas used for the plasma processing and the temperature of the placing table 2. In an embodiment, the processing gas used for plasma processing is, for example, fluorocarbon gas or hydrofluorocarbon gas. In addition, the plasma processing on the wafer W is executed, for example, in a state where the placing table 2 is cooled to a temperature of 0° C. or lower.

As illustrated in FIG. 3, irrespective of the difference between the processing conditions of the plasma processing on the wafer W, the greater the distance between the placing surface 6e of the placing table 2 and the wafer W, the greater the length of the intrusion range of the reaction product into the placing surface 6e. In addition, for each processing condition of the plasma processing on the wafer W, the degree of a change in the length of the intrusion range of the reaction product into the placing surface 6e is different with respect to the distance between the placing surface 6e of the placing table 2 and the wafer W.

In this way, in the plasma processing apparatus 10, the length of the intrusion range of the reaction product into the placing surface 6e changes according to the distance between the placing surface 6e of the placing table 2 and the wafer W. In addition, the degree of a change in the length of the intrusion range of the reaction product into the placing surface 6e is different for each processing condition of the plasma processing on the wafer W.

Therefore, for each processing condition of the plasma processing on the wafer W, the relationship between the distance between the placing surface 6e of the placing table 2 and the wafer W and the length of the intrusion range of the reaction product into the placing surface 6e measured on the basis of the end of the wafer W may be obtained in advance, for example, by experiments. Then, for each processing condition of the plasma processing on the wafer W, the relationship between the distance between the placing surface 6e of the placing table 2 and the wafer W and the length of the intrusion range of the reaction product into the placing surface 6e measured on the basis of the end of the wafer W is stored in the intrusion range information 131. For example, the intrusion range information 131 is a table in which the length of the intrusion range of the reaction product into the placing surface 6e is associated with the distance between the placing surface 6e of the placing table 2 and the wafer W.

Return to the explanation of FIG. 2. The process controller 110 includes an internal memory configured to store therein programs or data. The process controller 110 reads the control program stored in the storage unit 130, and executes a processing of the read control program. The process controller 110 functions as any of various processing units by the operation of the control program. For example, the process controller 110 includes a calculation unit 111 and an elevating control unit 112.

Meanwhile, in the plasma processing apparatus 10, when a plasma processing is performed on the wafer W, a reaction product is generated and adheres to and accumulates on, for example, the inner wall of the processing container 1. Part of the reaction product accumulated on, for example, the inner wall of the processing container 1 may volatilize from the reaction product and float as a gas in the processing container 1, and may adhere again to the placing surface 6e of the placing table 2. For example, in the plasma processing apparatus 10, when transferring the wafer W on which the plasma processing has been performed, the wafer W is raised from the placing surface 6e of the placing table 2 by the lifter pin 61. Therefore, in the plasma processing apparatus 10, the reaction product floating in the processing container 1 may intrude into a gap between the placing surface 6e of the placing table 2 and the wafer W, and may adhere to the placing surface 6e of the placing table 2. The adherence of the reaction product to the placing surface 6e of the placing table 2 is undesirable because it causes abnormality such as, for example, poor attraction of the wafer to the placing surface 6e of the placing table 2.

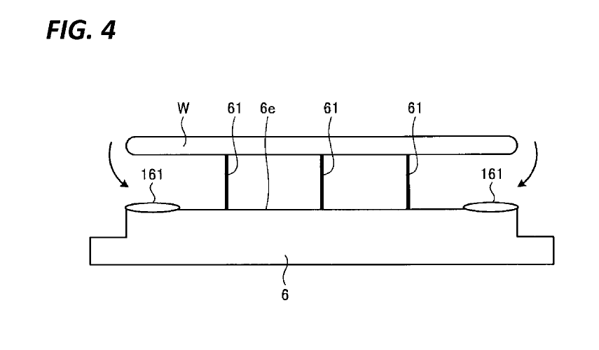

FIG. 4 is a view illustrating an exemplary state where the wafer W is raised from the placing surface 6e of the placing table 2. As illustrated in FIG. 4, in the plasma processing apparatus 10, when transferring the wafer W on which the plasma processing has been performed, the wafer W is raised from the placing surface 6e of the placing table 2 by the lifter pin 61. Therefore, a gap is formed between the placing surface 6e of the placing table 2 and the wafer W. Part of the reaction product accumulated on, for example, the inner wall of the processing container 1 may float as a volatile gas in the processing container 1, may intrude into the gap between the placing surface 6e of the placing table 2 and the wafer W, and may adhere, as a reaction product 161, to the placing surface 6e of the placing table 2. In particular, when the plasma processing is performed in a state where the placing table 2 is cooled to a temperature of 0° C. or lower, since condensation of the reaction product floating as a volatile gas easily occurs, the reaction product 161 tends to adhere to the placing surface 6e of the placing table 2. For example, in the plasma processing apparatus 10, when the reaction product 161 excessively adheres to the placing surface 6e of the placing table 2, abnormality such as, for example, poor attraction of the wafer to the placing surface 6 of the placing table 2 occurs.

Therefore, the plasma processing apparatus 10 controls the elevating mechanism 62 such that the placing surface 6e of the placing table 2 and the wafer W maintain therebetween the distance that prevents the intrusion of the reaction product during a period until the transfer of the wafer W begins after the completion of the plasma processing on the wafer W.

Return to the explanation of FIG. 2. The calculation unit 111 calculates, with reference to the intrusion range information 131, the distance between the placing surface 6e of the placing table 2 and the wafer W at which the length of the intrusion range of the reaction product corresponding to the processing condition of the executed plasma processing is equal to or less than a predetermined allowable length. For example, the calculation unit 111 calculates the distance between the placing surface 6e of the placing table 2 and the wafer W with reference to the intrusion range information 131 stored in advance in the storage unit 130. For example, it is assumed that the relationship between the distance and the intrusion range of the reaction product illustrated in FIG. 3 is stored in the intrusion range information 131 and that the processing condition of the executed plasma processing is the processing condition A. In this case, for example, the calculation unit 111 calculates, with reference to the intrusion range information 131, the distance of “0.20 mm” between the placing surface 6e of the placing table 2 and the wafer W when the length of the intrusion range corresponding to the processing condition A of the executed plasma processing is equal to or less than the predetermined allowable length of “2 mm”. The predetermined allowable length is determined based on at least the difference between the outer diameter of the placing surface 6e of the placing table 2 and the outer diameter of the wafer W. For example, when the outer diameter of the placing surface 6e of the placing table 2 is 296 mm and the outer diameter of the wafer W is 300 mm, the predetermined allowable length is determined to “2 mm” that is ½ of the difference (300−296=4 mm) between the outer diameter of the placing surface 6e of the placing table 2 and the outer diameter of the wafer W. In addition, for example, a dimensional error of the outer diameter of the placing surface 6e of the placing table 2 or a dimensional error of the outer diameter of the wafer W may be taken into consideration for the determination of the allowable length. In addition, the calculation of the distance between the placing surface 6e of the placing table 2 and the wafer W may be performed during a period until the transfer of the wafer W begins after the completion of the plasma processing on the wafer W, or may be performed before the plasma processing on the wafer W is completed.

The elevating control unit 112 controls the elevating mechanism 62, during a period until the transfer of the wafer W begins after the completion of the plasma processing on the wafer W, to hold the wafer W at a position where the placing surface 6e of the placing table 2 and the wafer W are spaced apart from each other by the distance that prevents the intrusion of the reaction product. For example, the elevating control unit 112 controls the elevating mechanism 62, during a period until the transfer of the wafer W begins after the completion of the plasma processing on the wafer W, to hold the wafer W at a position where the placing surface 6e of the placing table 2 and the wafer W are spaced apart from each other by the distance calculated by the calculation unit 111. The transfer of the wafer W begins, for example, at the timing when a transfer arm which has received a command to start the transfer of the wafer W on which the plasma processing has been performed arrives at the plasma processing apparatus 10 (processing container 1).

Then, the elevating control unit 112 controls the elevating mechanism 62, when the transfer of the wafer W begins, to raise the wafer W from the position where the wafer W is held. That is, at the timing when the transfer arm which has received the command to start the transfer of the wafer W on which the plasma processing has been performed arrives at the processing container 1, the elevating control unit 112 raises the wafer W from the position where the wafer W is held to a position where the wafer W is delivered to the transfer arm.

In this way, in the plasma processing apparatus 10, when transferring the wafer W on which the plasma processing has been performed, since the reaction product is prevented from intruding into the gap between the placing surface 6e of the placing table 2 and the wafer W, adherence of the reaction product to the placing surface 6e of the placing table 2 may be reduced.

[Flow of Control]

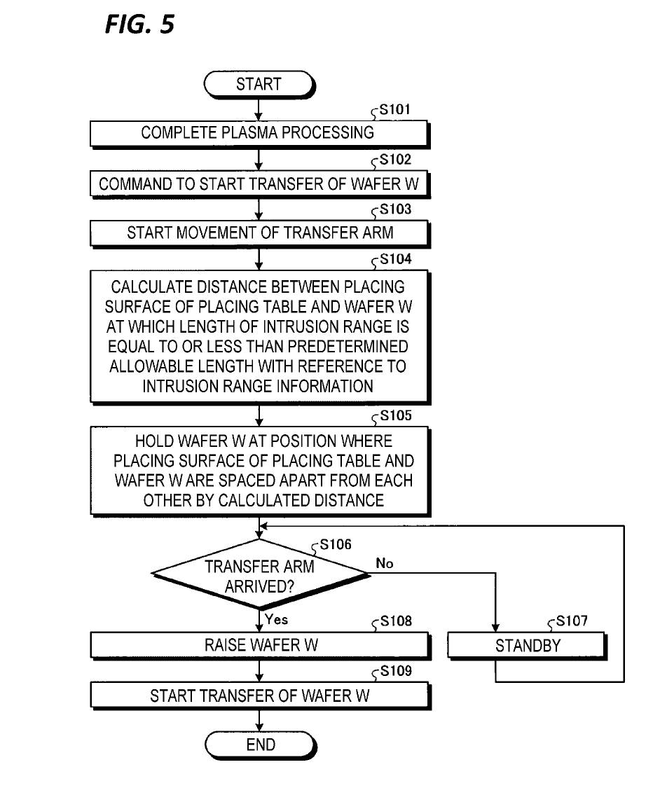

Next, a processing of transferring the wafer W using the plasma processing apparatus 10 according to an embodiment will be described. FIG. 5 is a flowchart illustrating an exemplary flow of a processing of transferring the wafer W according to an embodiment. The processing of transferring the wafer W is executed, for example, at the timing when the plasma processing on the wafer W is completed. In an embodiment, it is assumed that the plasma processing on the wafer W is executed in a state where the placing table 2 is cooled to a temperature of 0° C. or lower.

As illustrated in FIG. 5, when the plasma processing on the wafer W is completed (S101), a command to start the transfer of the wafer W on which the plasma processing has been performed is issued (S102), and the transfer arm which has received the command begins to move toward the plasma processing apparatus 10 (processing container 1) (S103).

The calculation unit 111 calculates, with reference to the intrusion range information 131, the distance between the placing surface 6e of the placing table 2 and the wafer W at which the length of the intrusion range of the reaction product corresponding to the processing condition of the executed plasma processing is equal to or less than a predetermined allowable length (S104).

The elevating control unit 112 controls the elevating mechanism 62 to hold the wafer W at a position where the placing surface 6e of the placing table 2 and the wafer W are spaced apart from each other by the distance calculated by the calculation unit 111 (S105).

The elevating control unit 112 stands by, in a state where the wafer W is held at the position where the placing surface 6e of the placing table 2 and the wafer W are spaced apart from each other by the distance calculated by the calculation unit 111, until the transfer arm arrives at the plasma processing apparatus 10 (processing container 1) (S106; No). That is, during a period until a transfer of the wafer W begins after the completion of the plasma processing on the wafer W, the elevating control unit 112 controls the elevating mechanism 62 such that the placing surface 6e of the placing table 2 and the wafer W maintain the distance that prevents the intrusion of the reaction product.

Meanwhile, when the transfer arm arrives at the plasma processing apparatus 10 (processing container 1) (S107; Yes), the elevating control unit 112 raises the wafer W from the position where the wafer W is held to a position where the wafer W is delivered to the transfer arm W (S108).

Thereafter, the transfer of the wafer W is started by the transfer arm (S109). That is, the transfer arm is carried into the processing container 1 and the wafer W is lowered by the elevating control unit 112, whereby the wafer W is delivered to the transfer arm. Then, the transfer arm transfers the delivered wafer W to the outside of the processing container 1.

As described above, the plasma processing apparatus 10 according to the embodiment includes the placing table 2, the elevating mechanism 62, and the elevating control unit 112. The placing table 2 has the placing surface 6e on which the wafer W that is an object of a plasma processing is placed. The elevating mechanism 62 raises and lowers the wafer W with respect to the placing surface 6e of the placing table 2. The elevating control unit 112 controls the elevating mechanism 62, during a period until a transfer of the wafer W begins after the completion of the plasma processing on the wafer W, to hold the wafer W at a position where the placing surface 6e of the placing table 2 and the wafer W are spaced apart from each other by the distance that prevents the intrusion of a reaction product. Then, the elevating control unit 112 controls the elevating mechanism 62 when the transfer of the wafer W begins to raise the wafer W from the position where the wafer W is held. Therefore, the plasma processing apparatus 10 may reduce adherence of the reaction product to the placing surface 6e of the placing table 2. In particular, even when the plasma processing is performed in a state where the placing table 2 is cooled to a temperature of 0° C. or lower, the plasma processing apparatus 10 may prevent the reaction product from introducing into the gap between the placing surface 6e of the placing table 2 and the wafer W, thereby preventing the adherence of the reaction product.

Although various embodiments have been described above, the disclosed technology is not limited to the above-described embodiments, and various modifications may be configured. For example, the above-described plasma processing apparatus 10 is a capacitively coupled plasma processing apparatus 10, but may be adopted in an arbitrary plasma processing apparatus 10. For example, the plasma processing apparatus 10 may be an arbitrary type of plasma processing apparatus 10, such as an inductively coupled plasma processing apparatus 10 or a plasma processing apparatus 10 configured to excite a gas with surface waves such as microwaves.

In addition, in the above-described embodiments, the wafer W is held at a position where the placing surface 6e of the placing table 2 and the wafer W are spaced apart from each other by the distance that prevents the intrusion of the reaction product, but the present disclosure is not limited thereto. For example, the plasma processing apparatus 10 may hold the wafer W at a position where the placing surface 6e of the placing table 2 and the wafer W are spaced apart from each other by the distance that prevents the intrusion of the reaction product while supplying an inert gas to the gap formed between the placing surface 6e of the placing table 2 and the wafer W. Therefore, the plasma processing apparatus 10 may prevent the intrusion of the reaction product into the gap between the placing surface 6e of the placing table 2 and the wafer W by the inert gas, thereby further reducing the adherence of the reaction product. The inert gas is, for example, N₂ gas, O₂ gas, or rare gas. In addition, the supply of the inert gas is performed using, for example, the gas supply pipe 30 configured to supply a cold heat transfer gas (backside gas) such as, for example, helium gas to the back surface of the wafer W.

In addition, the plasma processing apparatus 10 may perform dry cleaning to remove the reaction product accumulated on, for example, the inner wall of the processing container 1 by the plasma processing after the wafer W is transferred to the outside of the processing container 1 by the transfer arm 1. Therefore, the plasma processing apparatus 10 may prevent components of the reaction product accumulated on, for example, the inner wall of the processing container 1 from being discharged as a volatile gas into the processing chamber 1, thereby reducing the adherence of the reaction product to the placing surface 6e of the placing table 2 on which the wafer W is not placed.

In addition, in the plasma processing apparatus 10, a dummy wafer that is not an object of a plasma processing may be placed on the placing surface 6e of the placing table 2 after the wafer W is transferred to the outside of the processing container 1 by the transfer arm. Therefore, the plasma processing apparatus 10 may protect the placing surface 6e of the placing table 2 with the dummy wafer, thereby further reducing the adherence of the reaction product to the placing surface 6e of the placing table 2. In addition, the time for which the placement of the dummy wafer is continued is appropriately determined in consideration of the time from the completion of the plasma processing until the volatile components of the reaction product accumulated on, for example, the inner wall of the processing container 1, discharged into the processing container 1, are exhausted.

According to the present disclosure, it is possible to reduce adherence of a reaction product to a placing surface of a placing table.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a placing table having a placing surface on which a workpiece is placed to be subjected to a plasma processing;
an elevator configured to raise and lower the workpiece with respect to the placing surface of the placing table; and
an elevator controller configured to control the elevator, during a period until a transfer of the workpiece begins after a completion of the plasma processing on the workpiece, to hold the workpiece at a position where the placing surface of the placing table and the workpiece are spaced apart from each other by a distance that prevents an intrusion of a reaction product, and control the elevator, when the transfer of the workpiece begins, to raise the workpiece from the position where the workpiece is held.

2. The plasma processing apparatus of claim 1, wherein the plasma processing on the workpiece is executed in a state where the placing table is cooled to a temperature of 0° C. or lower.

3. The plasma processing apparatus of claim 1, further comprising:
a memory configured to store intrusion range information indicating a relationship between the distance between the placing surface of the placing table and the workpiece and a length of an intrusion range of the reaction product into the placing surface of the placing table measured on a basis of an end of the workpiece for each processing condition of the plasma processing; and
a calculator configured to calculate, with reference to the intrusion range information, the distance between the placing surface of the placing table and the workpiece at which the length of the intrusion range of the reaction product corresponding to the processing condition of the executed plasma processing is equal to or less than a predetermined allowable length,
wherein the elevator controller controls the elevator, during a period until a transfer of the workpiece begins after a completion of the plasma processing on the workpiece, to hold the workpiece at a position where the placing surface of the placing table and the workpiece are spaced apart from each other by the calculated distance.

4. The plasma processing apparatus of claim 3, wherein the predetermined allowable length is determined based on at least a difference between an outer diameter of the placing surface of the placing table and an outer diameter of the workpiece.

5. The plasma processing apparatus of claim 1, wherein the elevator controller holds the workpiece at the position while supplying an inert gas to a gap formed between the placing surface of the placing table and the workpiece.

6. The plasma processing apparatus of claim 2, further comprising:
a memory configured to store intrusion range information indicating a relationship between the distance between the placing surface of the placing table and the workpiece and a length of an intrusion range of the reaction product into the placing surface of the placing table measured on a basis of an end of the workpiece for each processing condition of the plasma processing; and
a calculator configured to calculate, with reference to the intrusion range information, the distance between the placing surface of the placing table and the workpiece at which the length of the intrusion range of the reaction product corresponding to the processing condition of the executed plasma processing is equal to or less than a predetermined allowable length,
wherein the elevator controller controls the elevator, during a period until a transfer of the workpiece begins after a completion of the plasma processing on the workpiece, to hold the workpiece at a position where the placing surface of the placing table and the workpiece are spaced apart from each other by the calculated distance.

7. The plasma processing apparatus of claim 6, wherein the predetermined allowable length is determined based on at least a difference between an outer diameter of the placing surface of the placing table and an outer diameter of the workpiece.

8. The plasma processing apparatus of claim 7, wherein the elevator controller holds the workpiece at the position while supplying an inert gas to a gap formed between the placing surface of the placing table and the workpiece.

9. A method of transferring a workpiece, the method comprising:
holding, by an elevator that raises and lowers the workpiece with respect to a placing surface of a placing table, the workpiece at a position where the placing surface of the placing table and the workpiece are spaced apart from each other by a distance that prevents intrusion of a reaction product, during a period until a transfer of the workpiece begins after a completion of the plasma processing on the workpiece; and
raising the workpiece from a position where the workpiece is held, when the transfer of the workpiece begins.
